(19) United States
(12) Patent Application Publication
(10) Pub. No.: US 2012/0146208 A1
(43) Pub. Date: Jun. 14, 2012

(54) SEMICONDUCTOR MODULE AND MANUFACTURING METHOD THEREOF

(75) Inventor: Jiro SHINKAI, Osaka-shi (JP)

(73) Assignee: SUMITOMO ELECTRIC INDUSTRIES, LTD., Osaka-shi (JP)

(21) Appl. No.: 13/314,022

(22) Filed: Dec. 7, 2011

Related U.S. Application Data
(60) Provisional application No. 61/421,022, filed on Dec. 8, 2010.

(30) Foreign Application Priority Data
Dec. 8, 2010 (JP) 2010-273122

(51) Int. Cl. H01L 23/498; H01L 21/58

(52) U.S. Cl. 257/691; 438/125; 257/E23.06; 257/E21.505

(57) ABSTRACT

A semiconductor module according to one embodiment includes a semiconductor chip, an insulating substrate, a case, an electrode, a busbar and a busbar support body. The semiconductor chip is mounted on the insulating substrate. The insulating substrate is housed inside the case. The electrode is disposed in the case and is electrically connected to the semiconductor chip. The electrode is supported on an electrode support section of the case. The busbar is bonded to the electrode and is led out of the case. The busbar support body holds the busbar and is mounted on the case.

### RELATED APPLICATIONS

This application claims priority to Provisional Application Ser. No. 61/421,022 filed on Dec. 8, 2010, which is hereby incorporated by reference in the entirety.

### BACKGROUND

1. Field

Embodiments of the present invention relate to a semiconductor module and a manufacturing method thereof.

2. Related Background Art

Semiconductor modules generally have a semiconductor chip, an insulating substrate, a busbar and a case. The semiconductor chip is mounted on an insulating substrate that has a conductive trace pattern. The insulating substrate on which the semiconductor chip is mounted is housed in the case. The case is integrally formed with the busbar, and the busbar is electrically connected to the semiconductor chip via the trace pattern. The busbar has an L-shape. As such a semiconductor module, for example, the semiconductor module disclosed in Japanese Patent No. 4089143 is known.

### SUMMARY

In the above-described conventional semiconductor module, the busbar extends outside the case in a direction that is perpendicular to a face of the insulating substrate on which the conductive trace pattern is formed. Therefore, the busbar may hampers the operation of connecting, by way of wires, the busbar and the trace pattern. Also, the busbar and the case are formed integrally with each other. This may result in a higher cost of the mold for molding the case.

In the technical field in question, therefore, there is a need for a semiconductor module, and a manufacturing method thereof, that can facilitate a connection process, and that allow reducing a manufacturing cost.

A semiconductor module according to one aspect of the present invention includes a semiconductor chip, an insulating substrate, a case, an electrode, a busbar and a busbar support body. The semiconductor chip is mounted on the insulating substrate. The insulating substrate is housed inside the case. The electrode is disposed in the case and is electrically connected to the semiconductor chip. The electrode is supported on an electrode support section of the case. The busbar is bonded to the electrode and is led out of the case. The busbar support body holds the busbar and is mounted on the case.

In the semiconductor module, a structure in which the busbar held by the busbar support body is bonded to the electrode provided in the case is employed. Specifically, the busbar support body that holds the busbar constitutes a component that is separate from the electrode and the case. Therefore, electrical connection between the electrode and the semiconductor chip, for instance, wiring of the electrode and the trace pattern on the insulating substrate, can be performed before bonding the busbar to the electrode. Accordingly, the busbar does not hamper an operation of the electrical connection. In addition, the busbar and the case are not integrally molded with each other. This allows reducing the manufacturing cost of the case.

In one embodiment, the electrode support section of the case may be formed in a raised shape so as to have an electrode mounting surface that includes a first region and a second region. In this embodiment, a distance between the insulating substrate and the second region in a first direction parallel to the insulating substrate may be greater than a distance between the insulating substrate and the first region in the first direction; and a distance between the insulating substrate and the second region in a second direction perpendicular to the insulating substrate may be smaller than a distance between the insulating substrate and the first region in the second direction. In this embodiment, the electrode may be mounted across the first region and the second region, and the busbar support body may be mounted at the second region.

According to the embodiment, the second region is recessed with respect to the first region. Therefore, it is possible to mount the busbar support body on the second region and to bond the busbar to the electrode at the second region. As a result, it becomes possible to prevent outflow of the bonding member beyond the first region.

In one embodiment, a groove is formed in the electrode support section, along an edge of the electrode that is connected to the busbar. Even if the bonding member for bonding the busbar and electrode flows out, the outflowing bonding member can be absorbed by the groove in such an embodiment. The electrode and the busbar can be bonded by way of, for instance, a solder paste or a conductive paste.

In one embodiment, one of the case and the busbar support body may be formed with a recess into which at least part of the other of the case and the busbar support body fits. According to such an embodiment, the busbar support body can be positioned easily with respect to the case through fitting of the other member in the recess of the one member.

Another aspect of the present invention relates to a method for manufacturing a semiconductor module. The method includes (a) housing, in a case, an insulating substrate having a semiconductor chip mounted thereon, an electrode being supported on an electrode support section in the case, and the electrode being disposed inside the case; (b) electrically connecting the semiconductor chip and the electrode; (c) mounting, on the case, a busbar support body that holds a busbar; and (d) bonding the electrode and the busbar.

Such a manufacturing method allows bonding the busbar to the electrode after the step of electrically connecting the semiconductor chip and the electrode. Therefore, the busbar does not hamper the operation of electrically connecting the semiconductor chip and the electrode. Also, the busbar and the case are molded integrally together with each other. This allows reducing the manufacturing costs of the case.

As explained above, a semiconductor module, and a manufacturing method thereof, that can facilitate a connection process, and that allow reducing a manufacturing cost are provided.

### BRIEF DESCRIPTION OF THE DRAWINGS

FIG. 1 shows a perspective-view of a semiconductor module according to one embodiment;

FIG. 2 shows an exploded perspective-view of the semiconductor module illustrated in FIG. 1;

FIG. 3 shows another exploded perspective-view of the semiconductor module illustrated in FIG. 1;

FIG. 4 shows an enlarged perspective-view illustrating a part of the semiconductor module illustrated in FIG. 3;

FIG. 5 shows a plan-view of a semiconductor chip and an insulating substrate according to one embodiment;

FIG. 6 shows an enlarged, exploded perspective-view diagram illustrating a portion of a semiconductor module according to another embodiment;

FIG. 7 is a diagram illustrating a step of a manufacturing method of a semiconductor module according to one embodiment;

FIG. 8 is a diagram illustrating a step of a manufacturing method of a semiconductor module according to one embodiment; and

FIG. 9 is a diagram illustrating a step of a manufacturing method of a semiconductor module according to one embodiment.

### DETAILED DESCRIPTION

Embodiments are explained with reference to accompanying drawings. In the drawings, identical or equivalent portions are denoted with the same reference symbol.

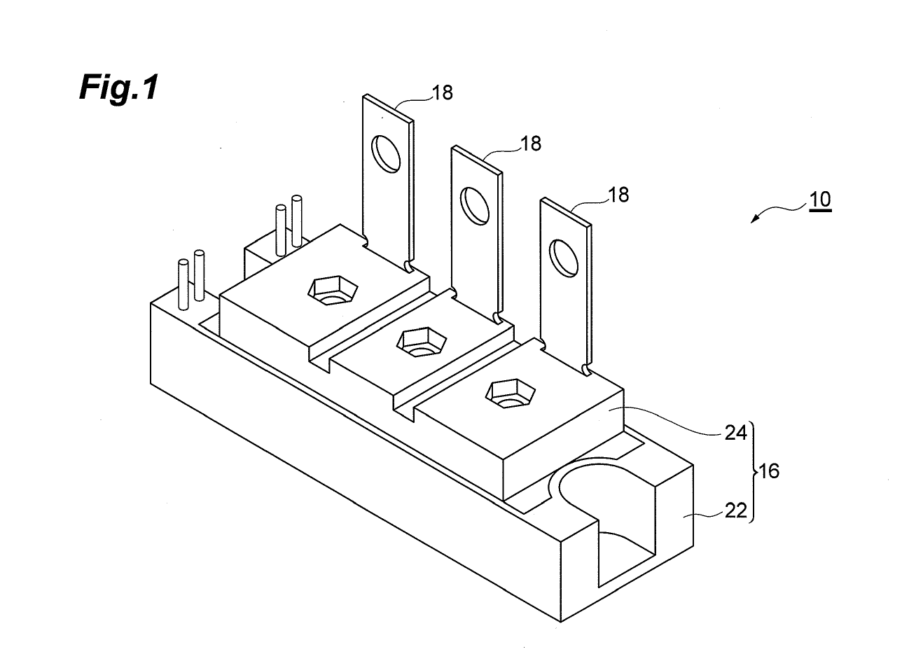

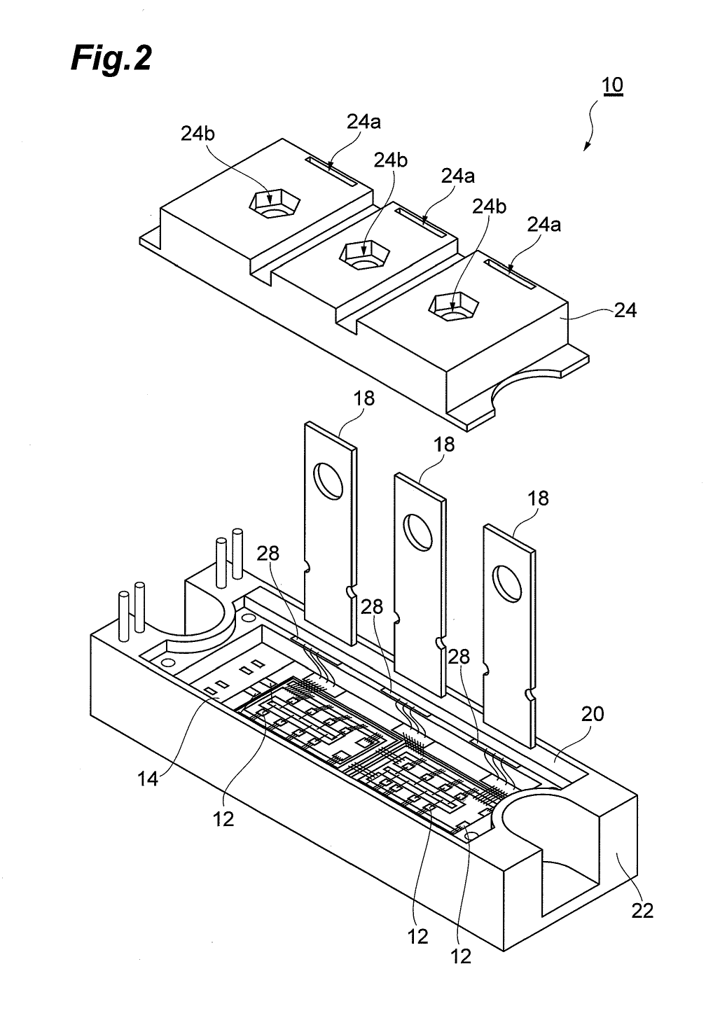

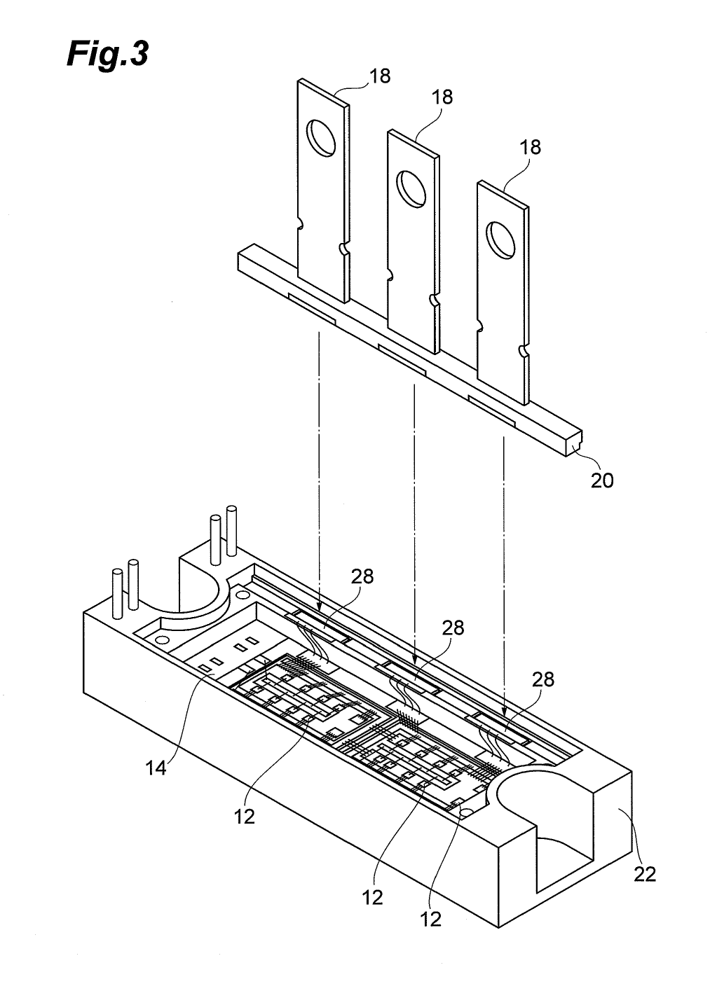

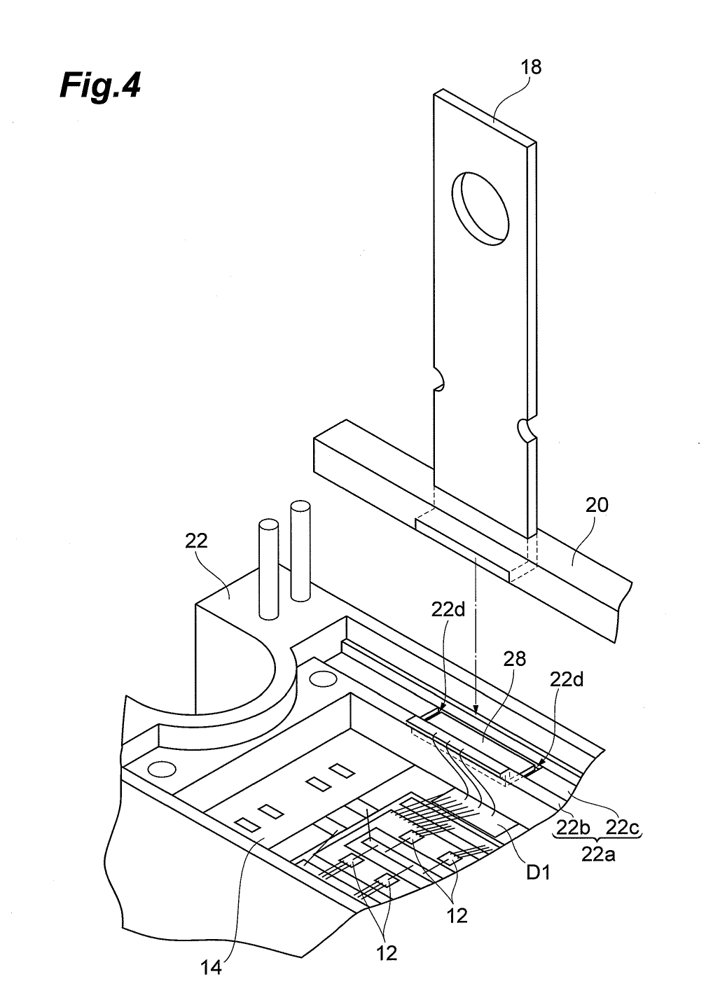

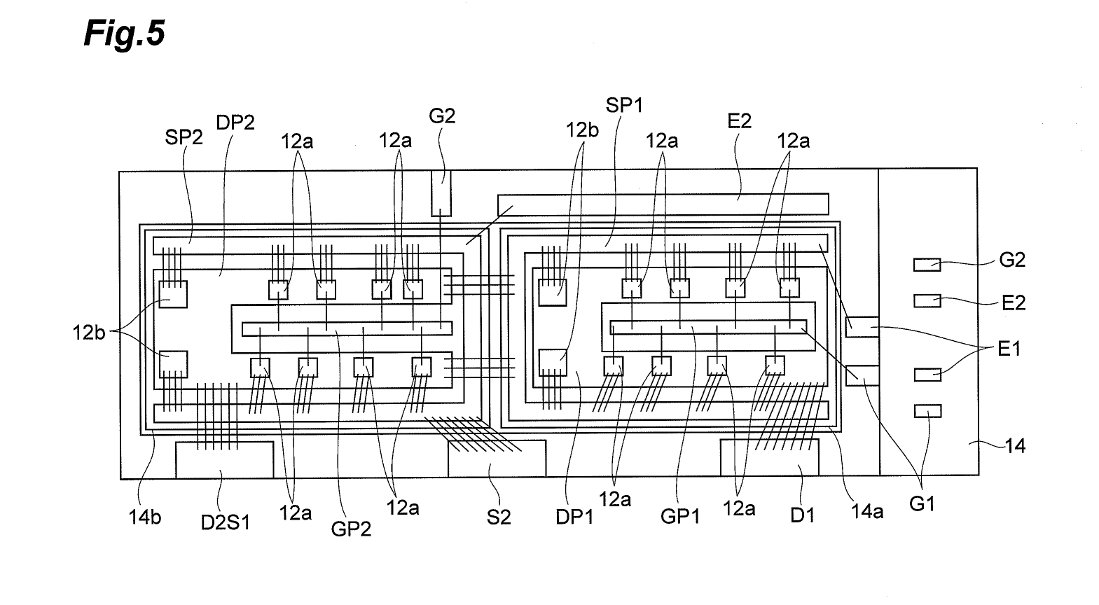

A semiconductor module according to one embodiment is explained with reference to FIG. 1 to FIG. 5. FIG. 1 shows a perspective-view of a semiconductor module according to one embodiment. FIG. 2 shows an exploded perspective-view of the semiconductor module illustrated in FIG. 1, wherein the figure illustrates a state in which a lid is removed from a semiconductor module. FIG. 3 shows another exploded perspective-view of the semiconductor module illustrated in FIG. 1, wherein the figure illustrates a state in which the lid is omitted, and a busbar and a busbar support body are separated. FIG. 4 shows an enlarged perspective-view illustrating an enlarged part of the semiconductor module illustrated in FIG. 3. FIG. 5 shows a plan-view of a semiconductor chip and an insulating substrate according to one embodiment.

As illustrated in FIG. 1 to FIG. 3, the semiconductor module 10 includes one or more semiconductor chips 12, an insulating substrate 14, a case 16, busbars 18 and a busbar support body 20. In the semiconductor module 10, the semiconductor chips 12 are housed inside the case 16, and the busbars 18, which are electrically connected to the semiconductor chips 12, are led out of the case 16.

As illustrated in FIG. 2 to FIG. 4, the one or more semiconductor chips 12 are mounted on the insulating substrate 14. The semiconductor chips 12 may be, for instance, MOS-FETs or diodes. The insulating substrate 14 may be formed of a material such as, for instance, AlN, SiN or Al₂O₃. AlN and SiN have excellent thermal conductivity, while Al₂O₃ allows manufacturing a low-cost insulating substrate. SiN has a thermal conductivity close to that of Cu. Therefore, SiN allows enhancing the reliability of the semiconductor module 10 in a case where a below-described mounting plate is made up of Cu.

The insulating substrate 14 includes conductive trace patterns formed on one main surface of the insulating substrate 14. The semiconductor chips 12 are electrically connected to the trace patterns through wires or the like. FIG. 5 illustrates a more detailed example of the semiconductor chips 12 and the insulating substrate 14. FIG. 5 illustrates a plurality of MOS-FETs 12a and plurality of diodes 12b as examples of the semiconductor chips 12.

In one embodiment, a main surface of the insulating substrate 14 may include a first substrate region 14a and a second substrate region 14b. In the first substrate region 14a, a gate pattern GP1, a source pattern SP1 and a drain pattern DP1 are provided, as trace patterns. The MOS-FETs 12a are mounted on the drain pattern DP1 so that rear-face drain electrodes are electrically connected the drain pattern DP1. The gate electrodes of the MOS-FETs 12a are connected to the gate pattern GP 1 through wires, and the source electrodes thereof are connected to the source pattern SP1 through other wires. The diodes 12b are mounted on the drain pattern DP1. A gate pattern GP1 is electrically connected to other gate patterns G1. A source pattern SP1 is connected to auxiliary emitter patterns E1 through wires. The drain pattern DP1 is connected through wires to a drain pattern D1 that is provided on one edge portion of the insulating substrate 14.

In the second substrate region 14b, a gate pattern GP2, a source pattern SP2 and a drain pattern DP2 are likewise provided, as trace patterns. The MOS-FETs 12a are mounted on the drain pattern DP2 so that rear-face drain electrodes are electrically connected to the drain pattern DP2. The gate electrodes of the MOS-FETs 12a are connected to the gate pattern GP2 through wires, and the source electrodes thereof are connected to the source pattern SP2 through other wires. The diodes 12b are mounted on the drain pattern DP1. A gate pattern GP2 is electrically connected to another gate pattern G2. A source pattern SP2 is connected, through wires, to an auxiliary emitter pattern E2 and a source pattern S2 that is provided on one edge portion of the insulating substrate 14. The drain pattern DP2 is connected, through wires, to a source pattern D2S1 that is provided on one edge portion of the insulating substrate 14.

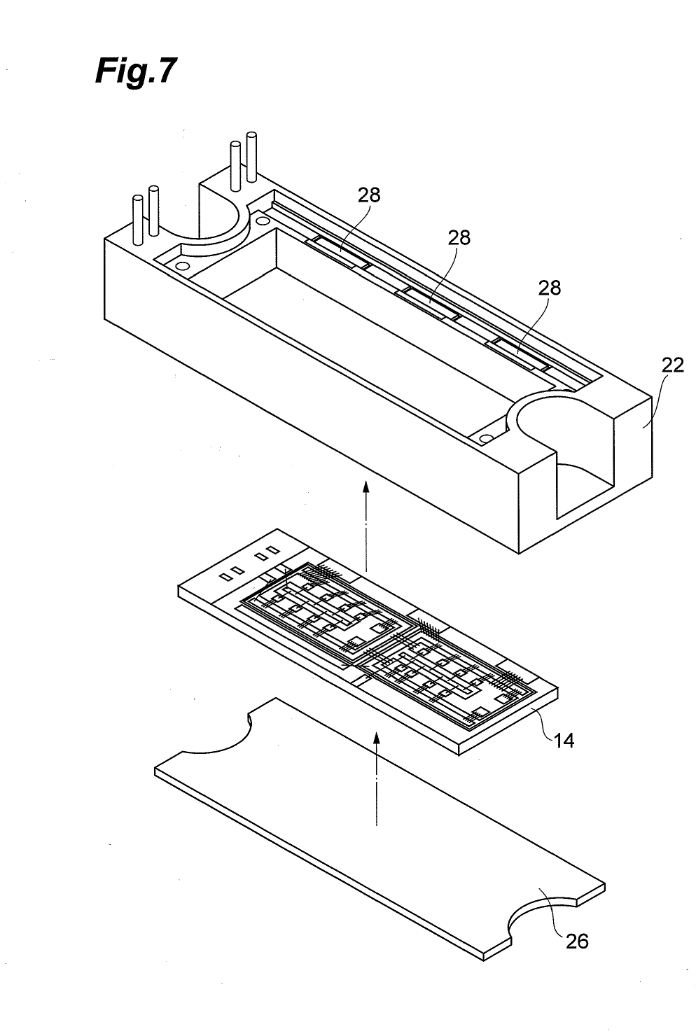

The case 16 houses therein the insulating substrate 14 on which the semiconductor chips 12 are mounted as described above. In one embodiment, as illustrated in FIG. 1 to FIG. 3, the case 16 may include a frame body 22, a lid 24 and a mounting plate 26 (see FIG. 7).

The frame body 22 constitutes a side wall of the case 16 so as to surround the periphery of the insulating substrate 14. The lid 24 is attached to the frame body 22 so as to close an upper opening of the frame body 22. Holes 24a and screw holes 24b are formed in the lid 24. The holes 24a are formed in the lid 24 for the purpose of leading the busbars 18 out. The screw holes 24b are formed in the lid 24 for the purpose of fixing, through screwing, the busbars 18 that extend outside from the holes 24a and are then bent so as to extend along the top face of the lid 24. The frame body 22 and the lid 24 may be manufactured, for instance, through molding of a thermosetting resin or a thermoplastic resin.

The mounting plate 26 is attached to the frame body 22 so as to close a lower opening of the frame body 22. The mounting plate 26 mounts, on a main surface thereof, the insulating substrate 14 on which the semiconductor chips 12 are mounted. The mounting plate 26 may be made up of a metal, for instance Cu.

FIG. 3 and FIG. 4 are referenced next. A plurality of electrodes 28 is supported on the case 16. In one embodiment, the frame body 22 of the case 16 includes the electrode support section 22a, and the plurality of electrodes 28 are supported by the electrode support section 22a. In the embodiment shown in FIG. 3 and FIG. 4, the electrode support section 22a is integrally formed with one side wall of the frame body 22.

In one embodiment, the electrode support section 22a is formed in a raised shape with respect to the mounting plate 26. The top face of the electrode support section 22a, i.e. the electrode mounting surface, has a first region 22b and a second region 22e. In a direction parallel to the main surface of the insulating substrate 14, the distance between the first region 22b and the insulating substrate 14 is smaller than the distance between the second region 22c and the insulating substrate 14. In a direction perpendicular to the main surface of the insulating substrate 14, the distance between the first region 22b and the insulating substrate 14 is greater than the distance between the second region 22c and the insulating substrate 14. That is, the second region 22c is formed in a recess with respect to the first region 22b.

The above-described plurality of electrodes 28 extend across the first region 22b and the second region 22c so as to be exposed at the electrode support surface. The electrodes 28 are present inside the case 16. The electrodes 28 and the frame body 22 of the case 16 may be formed integrally.

The portions of the electrodes 28 disposed on the first region 22b may be connected to the trace patterns of the above-described insulating substrate 14 through wires. In the example illustrated in FIG. 3 and FIG. 5, three electrodes 28 may be connected to the source pattern D2S1, the source pattern S2 and the drain pattern D1.

As illustrated in FIG. 3 and FIG. 4, the busbar support body 20 that supports the busbars 18 can be mounted on the second region 22c, i.e. in the recess of the electrode support section 22a. The busbars 18 are substantially band-shaped metallic members. The base portion of the busbars 18 extend parallelly to the electrodes 28 at the second region 22c, and thereafter the busbars 18 are bent and extend in a direction that is perpendicular to the main surface of the insulating substrate 14.

The busbar support body 20 is a component that is separate from the case 16. The busbar support body 20 may be formed integrally with the busbars 18 using the same material as that of the frame body 22. In the embodiment illustrated in FIG. 3 and FIG. 4, the busbar support body 20 is formed integrally with the base portion of the busbars 18 so that the busbars 18 are exposed at the lower face of the busbar support body 20. The base portion of the busbars 18 may be bonded to the electrodes 28 that are provided in the second region 22c, through a bonding member, such as a silver paste or a solder preform.

In the semiconductor module 10, thus, the busbar support body 20 is mounted in a recess of the electrode support section 22a, and hence the busbar support body 20 can be positioned easily. In addition, the first region 22b can prevent the bonding member from outflowing.

In one embodiment, as illustrated in FIG. 3 and FIG. 4, grooves 22d may be formed, along the edges of the electrodes 28, in the second region 22c of the electrode support section 22a. In such an embodiment, the outflowing bonding member can be absorbed by the grooves 22d.

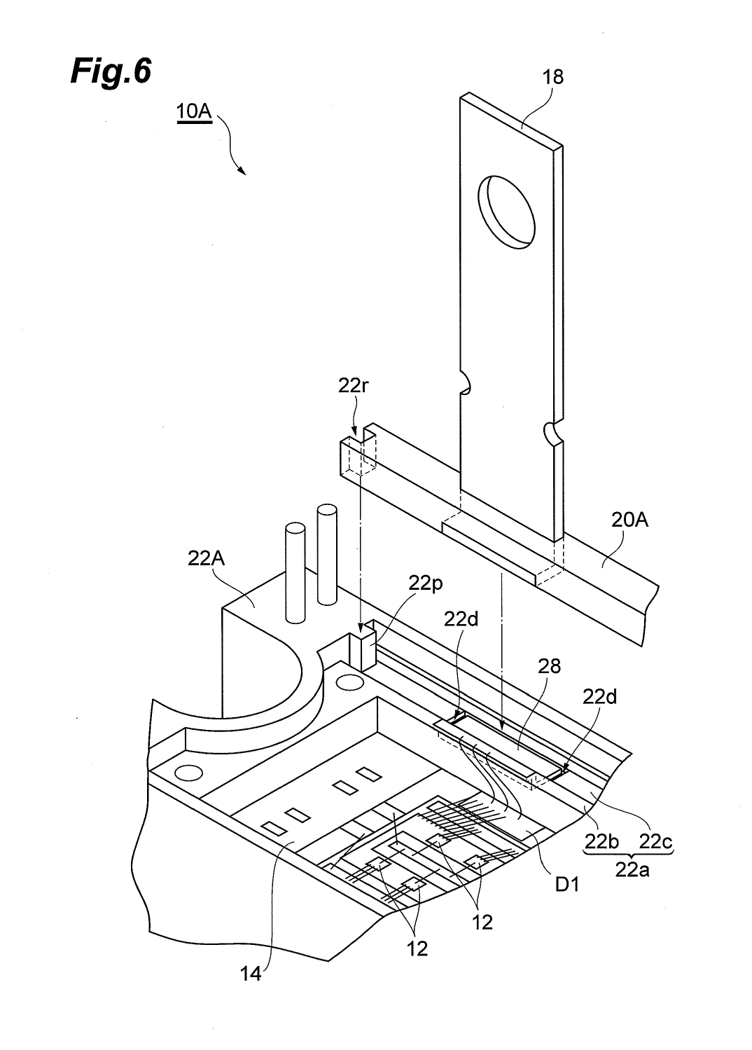

An explanation follows next, with reference to FIG. 6, on a semiconductor module according to another embodiment. FIG. 6 is an enlarged, exploded perspective-view illustrating a portion of a semiconductor module according to another embodiment. A semiconductor module 10A illustrated in FIG. 6 differs from the semiconductor module 10 in that the semiconductor module 10A includes a busbar support body 20A and a frame body 22A instead of the busbar support body 20 and the frame body 22.

In the busbar support body 20A, a recess 20r extending in a direction substantially perpendicular to the main surface of the insulating substrate 14 is formed. In the frame body 22A, a projection 22p that can fit into the recess 20r is formed, in addition to the same structure as the frame body 22. The projection 22p extends also in a direction perpendicular to the main surface of the insulating substrate 14. The projection 22p and the recess 20r have the function of guiding the busbar support body 20A in the second region 22c upon mounting of the busbar support body 20A on the case 16. The semiconductor module 10A can be assembled more easily thanks to the projection 22p and the recess 20r.

An explanation follows next, with reference to FIG. 7 to FIG. 9, on a method for manufacturing a semiconductor module according to one embodiment. FIG. 7 to FIG. 9 illustrate various steps in a method for manufacturing the semiconductor module 10. In the method for manufacturing the semiconductor module 10, the frame body 22 that support the electrodes 28 and the lid 24 are molded beforehand. Separately from this step, the busbar support body 20 that supports the busbars 18 is likewise molded beforehand.

In a subsequent step, the insulating substrate 14 having the semiconductor chips 12 mounted thereon is in turn mounted on the mounting plate 26, as illustrated in FIG. 7. The mounting plate 26 is then attached to the frame body 22. As a result, the insulating substrate 14 having the semiconductor chips 12 mounted thereon becomes housed in the case 16.

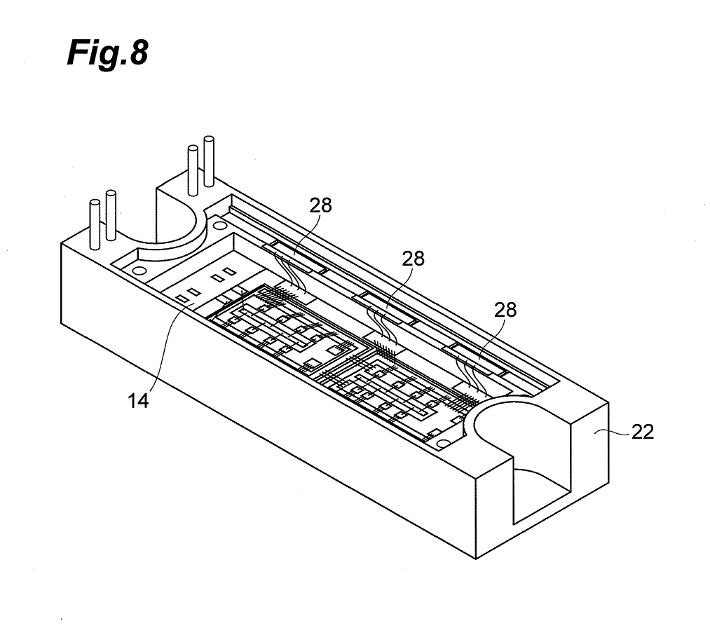

In a subsequent step, the electrodes 28 and the trace patterns of the insulating substrate 14 are connected through wires, as illustrated in FIG. 8. The semiconductor chips 12 and the electrodes 28 become electrically connected as a result. In the above-described example, three electrodes 28 are respectively connected, through wires, to the source pattern D2S1, the source pattern S2 and the drain pattern D1.

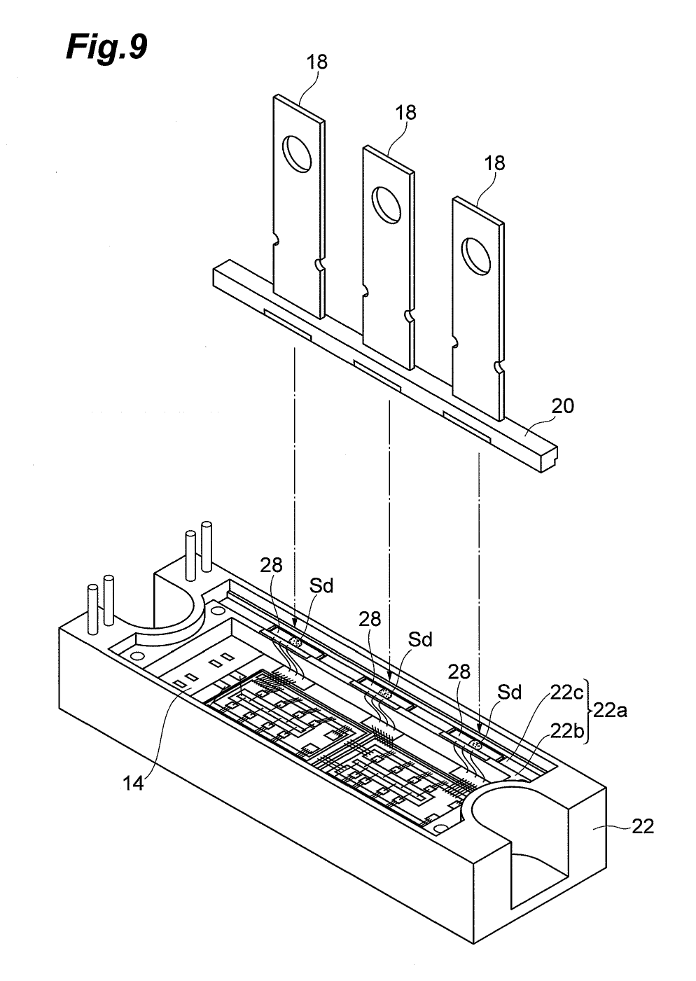

In a subsequent step, the busbar support body 20 that supports the busbars 18 is mounted on the second region 22c of the electrode support section 22a, as illustrated in FIG. 9. The electrodes 28 and the busbars 18 are then bonded to each other through a bonding member Sd that is provided beforehand on the electrodes 28 present in the second region 22c.

Lastly, the lid 24 is attached to the frame body 22 so that the busbars 18 are led out through the holes 24a, to complete thereby the semiconductor module 10 illustrated in FIG. 1.

In the semiconductor modules according to the various embodiments described above, the busbar support body that supports the busbars 18 is separate from the electrodes 28 and from the case 16. As a result, the busbars 18 and the electrodes 28 can be connected after the electrodes 28 and the semiconductor chips 12 are electrically connected with each other. Accordingly, the busbars 18 do not hamper the operation of electrically connecting the electrodes 28 and the semiconductor chips 12, i.e. the operation of connecting the trace patterns of the insulating substrate 14 with the electrodes 28 through wires. Therefore, the semiconductor module can facilitate a connection process through wires or the like. In addition, the busbars 18 are separate from the case 16, and hence the cost of the mold used for molding the case 16 can be reduced.

It should be noted that the present invention is not limited to the above-described embodiments, and can accommodate various modifications. For instance, instead of the projection 22p and the recess 20r, a recess may be formed in the frame body, and a projection may be formed in the busbar support body, such that the projection can fit into the recess.

What is claimed is:

1. A semiconductor module, comprising:
a semiconductor chip;
an insulating substrate mounting the semiconductor chip thereon;
a case housing the insulating substrate therein;
an electrode disposed in the case and electrically connected to the semiconductor chip, the electrode being supported on an electrode support section of the case;
a busbar bonded to the electrode and led out of the case; and
a busbar support body holding the busbar and mounted on the case.

2. The semiconductor module according to claim 1,
wherein the electrode support section is formed in a raised shape so as to have an electrode mounting surface that includes a first region and a second region,
a distance between the insulating substrate and the second region in a first direction parallel to the insulating substrate is greater than a distance between the insulating substrate and the first region in the first direction,
a distance between the insulating substrate and the second region in a second direction perpendicular to the insulating substrate is smaller than a distance between the insulating substrate and the first region in the second direction,
the electrode is mounted across the first region and the second region, and
the busbar support body is mounted on the second region.

3. The semiconductor module according to claim 1,
wherein a groove is formed in the electrode support section, along an edge of the electrode that is connected to the busbar.

4. The semiconductor module according to claim 1,
wherein one of the case and the busbar support body is formed with a recess into which at least part of the other of the case and the busbar support body fits.

5. The semiconductor module according to claim 1,
wherein the electrode and the busbar are bonded through solder paste or a conductive paste.

6. A method for manufacturing a semiconductor module comprising:
housing, in a case, an insulating substrate mounting having a semiconductor chip mounted thereon, wherein an electrode is supported on an electrode support section in the case, and the electrode is disposed inside the case;
electrically connecting the semiconductor chip and the electrode;
mounting, on the case, a busbar support body that holds a busbar; and
bonding the electrode and the busbar.
